(19) United States
(12) Patent Application Publication
(10) Pub. No.: US 2026/0068696 A1
(43) Pub. Date: Mar. 5, 2026

(54) FAN-OUT WAFER LEVEL PACKAGING UNIT

(71) Applicant: WALTON ADVANCED ENGINEERING, INC., KAOHSIUNG (TW)

(72) Inventors: HONG-CHI YU, KAOHSIUNG (TW); CHUN-JUNG LIN, KAOHSIUNG (TW); RUEI-TING GU, KAOHSIUNG (TW)

(21) Appl. No.: 19/315,681

(22) Filed: Sep. 1, 2025

(30) Foreign Application Priority Data
Sep. 2, 2024 (TW) 113133095

(51) Int. Cl. H01L 23/00

(52) U.S. Cl. CPC H01L 24/24

(57) ABSTRACT

A fan-out wafer-level packaging (FOWLP) unit is provided. The FOWLP unit includes a substrate, a first dielectric layer, a plurality of first conductive circuits, at least one first die, a second dielectric layer, at least one conductive pillar, a plurality of second conductive circuits, a third dielectric layer, a plurality of third conductive circuits, and at least one second die. The first die and the second die are electrically connected with the outside through first die pads around a chip area on a second surface of the first die. The first conductive circuits, the second conductive circuits, and the third conductive circuits are produced by filling of metal pastes into slots and grinding of the metal paste. Thereby problems of FOWLP technology available now generated during manufacturing of the respective conductive circuits including higher manufacturing cost and environmental unfriendly can be solved.

### CROSS-REFERENCE TO RELATED APPLICATIONS

This non-provisional application claims priority under 35 U.S.C. § 119 (a) on Patent Application No(s). 113133095 filed in Taiwan, R.O.C. on Sep. 2, 2024, the entire contents of which are hereby incorporated by reference.

### BACKGROUND OF THE INVENTION

The present invention relates to a packaging unit, especially to a fan-out wafer level packaging (FOWLP) unit.

In the advanced packaging process such as FOWLP, a redistribution layer (RDL) is the most critical because respective conductive circuits in the RDL make a plurality of die pads on dies have electrical extension in the XY plane and interconnections. Thus a plurality of bonding pads is arranged around the die in a more distributed manner. Thereby design, space, and reliability of the respective conductive circuits are effectively improved. Yet how to keep balance between the electrical extension in the XY plane and interconnections of the conductive circuits and the compact design to a certain degree, the most critical point is the manufacturing of the respective conductive circuits in the RDL.

However, the formation of the respective conductive circuits in the RDL of the FOWLP technology available now is by chemical plating or electroplating. Thus not only cost for material and manufacturing is high, the manufacturing process is also not environmental friendly.

Moreover, when efficiency or computational power of the FOWLP unit needs to be increased, additional dies are required. How the dies inside and outside the packaging unit are electrically connected to the inside or the outside is also an important issue which needs to be addressed.

### SUMMARY OF THE INVENTION

Therefore, it is a primary object of the present invention to provide a fan-out wafer-level packaging (FOWLP) unit which includes a substrate, a first dielectric layer, a plurality of first conductive circuits, at least one first die, a second dielectric layer, at least one conductive pillar, a plurality of second conductive circuits, a third dielectric layer, a plurality of third conductive circuits, and at least one second die. The first die and the second die are electrically connected with the outside through first die pads around a chip area on a second surface of the first die. The first, the second, and the third conductive circuits are produced by filling of metal pastes into slots and grinding of the metal paste. Thereby problems of the FOWLP module available now generated during manufacturing of the respective conductive circuits including higher manufacturing cost and less environmental benefit can be solved.

In order to achieve the above object, a fan-out wafer-level packaging (FOWLP) unit according to the present invention is provided. The FOWLP unit includes a substrate, a first dielectric layer, a plurality of first conductive circuits, at least one first die, a second dielectric layer, at least one conductive pillar, a plurality of second conductive circuits, a third dielectric layer, a plurality of third conductive circuits, and at least one second die. The substrate is provided with a first surface, a second surface opposite to the first surface, and a substrate dielectric layer disposed on the second surface. The first dielectric layer is arranged over the substrate dielectric layer of the substrate and provided with at least first slot extending horizontally. The respective first conductive circuits are formed by a metal paste filled into the respective first slots correspondingly. The first die is cut from a wafer and provided with a first surface and a second surface opposite to the first surface. A plurality of first die pads is disposed on the first surface while a range perpendicular to the second surface is defined as a chip area. The first chip is having at least one chip conductive pillar penetrating the first surface and the second surface so that the first surface is electrically connected to the second surface by the conductive pillars. The first surface of the first die is disposed on the first conductive circuits by flip chip so that the first die pads and the first conductive circuits are electrically connected. As to the second dielectric layer, it is disposed over the first dielectric layer and covering the first die. The second dielectric layer is provided with at least one second slot extending in a horizontal direction and at least one insertion hole. The second slot is communicating with the insertion hole which is communicating with the first slot. The conductive pillar is formed in the insertion hole, exposed through the insertion hole, and electrically connected to the first conductive circuits. The respective second conductive circuits are formed by a metal paste filled into the respective second slots correspondingly and electrically connected to the conductive pillar. The third dielectric layer is disposed over the second dielectric layer and the second conductive circuits. The third dielectric layer is provided with at least one opening extending in a horizontal direction. The third conductive circuits are formed by a metal paste filled into the respective openings. At least one of the openings is located around the chip area on the second surface of the first die. The third conductive circuits are exposed through the openings to form a first bonding pad in each of the openings. The third conductive circuits are electrically connected with the second conductive circuits. The second die is cut from a wafer and provided with a first surface and a second surface opposite to the first surface. A plurality of die pads is disposed on the first surface. The second chip is provided with at least one chip conductive pillar penetrating the first surface and the second surface so that the first surface is electrically connected to the second surface by the conductive pillar. The first surface of the second die is disposed on the third conductive circuits by flip chip so that the die pads and the third conductive circuits are electrically connected. The second die is electrically connected to the first die through the die pads of the second die, the third conductive circuits, the second conductive circuits, the conductive pillars, the first conductive circuits, and the first die pads of the first die in turn. The second die is electrically connected to the outside through the die pads of the second die, the third conductive circuits, the second conductive circuits, the third conductive circuits, and the first die pads located around the chip area on the second surface of the first die in turn. The first die is electrically connected to the outside through the first die pads of the first die, the first conductive circuits, the conductive pillars, the second conductive circuits, the third conductive circuits, and the first die pads located around the chip area on the second surface of the first die in turn. Thereby the FOWLP unit is formed. A method of manufacturing the FOWLP unit includes the following steps. Step S1: providing a substrate having a first surface and a second surface opposite to the first surface and having a substrate dielectric layer on the second surface. Step S2: producing a plurality of first conductive circuits on the substrate dielectric layer by filling a metal paste into slots and grinding the metal paste. First paving a first dielectric layer over the second surface of the substrate. Then forming a plurality of first slots horizontally on the first dielectric layer. Next filling a metal paste into the first slots and a level of the metal paste is higher than a surface of the first dielectric layer. Lastly grinding the metal paste with the level higher than the surface of the first dielectric layer to make a surface of the metal paste flush with the surface of the first dielectric layer and form a plurality of the first conductive circuits. Step S3: arranging a plurality of first dies cut from at least one wafer on the second surface of the substrate with an interval between the two adjacent first dies. Each of the first dies includes a first surface and a second surface opposite to the first surface. The first surface is provided with a plurality of first die pads and a range perpendicular to the second surface is defined as a chip area. The first chip includes at least one chip conductive pillar penetrating the first surface and the second surface of the first die. The first surface of the first die is disposed on the first conductive circuits by flip chip so that the first die pads of the first die and the first conductive circuits are electrically connected. Step S4: producing a plurality of second conductive circuits on the second surface of the first die by filling a metal paste into slots and grinding the metal paste. First paving a second dielectric layer over the second surface of the substrate and the respective first dies. The second dielectric layer covers the respective first dies. Then forming a plurality of second slots horizontally on the second dielectric layer and a plurality of insertion holes penetrating the second dielectric layer. The first die pads of the first die are exposed through the second slots. The insertion holes are communicating with the first slots and the second slots. Later forming a conductive pillar in the insertion hole and filling a metal paste into the second slots and a level of the metal paste is higher than a surface of the second dielectric layer. Lastly grinding the metal paste with the level higher than the surface of the second dielectric layer to make a surface of the metal paste flush with the surface of the second dielectric layer and form a plurality of the second conductive circuits. Step S5: producing a plurality of third conductive circuits on the second dielectric layer by filling a metal paste into slots and grinding the metal paste. First paving a third dielectric layer over the second dielectric layer. Then forming a plurality of openings horizontally on the third dielectric layer. Later filling a metal paste into the openings and a level of the metal paste is higher than a surface of the third dielectric layer. Lastly grinding the metal paste with the level higher than the surface of the third dielectric layer to make a surface of the metal paste flush with the surface of the third dielectric layer and form a plurality of the third conductive circuits. At least one of the openings is located around the chip area on the second surface of the first die. The third conductive circuits are exposed through the openings to form a first bonding pad in each of the openings. Step S6: arranging a plurality of second dies cut from at least one wafer at the third conductive circuits with an interval between the two adjacent second dies. Each of the second dies includes a first surface and a second surface opposite to the first surface. The first surface is provided with a plurality of die pads. Each of the second dies is provided with at least one chip conductive pillar penetrating the first surface and the second surface of the second die. The first surface of the second die is disposed on the third conductive circuits by flip chip so that the die pads of the second die and the third conductive circuits are electrically connected. Step S7: performing cutting to form a plurality of the FOWLP units.

Preferably, the substrate can be a silicon substrate, a glass substrate, or a ceramic substrate.

Preferably, the metal pastes which form the first conductive circuits, the second conductive circuits, and the third conductive circuits include silver paste, nano-scale silver paste, copper paste, and nano-scale copper paste.

Preferably, a solder ball is mounted to each of the openings and electrically connected with the first die pad in the opening. Thereby the FOWLP unit can be electrically connected and fixed on a printed circuit board (PCB) by the solder balls.

Another FOWLP unit is provided and considered as another embodiment of the present invention. This embodiment and the above embodiment have the same components. As to the structure and the method of manufacturing the FOWLP unit, the difference between this embodiment and the above one is described below.
(1) As to the structure, the substrate of this embodiment further includes at least one substrate conductive pillar penetrating the substrate dielectric layer, the first surface, and the second surface of the substrate. The substrate conductive pillar is exposed through the substrate to form a second bonding pad on the substrate.
(2) As to the structure, the second die is further connected with the outside through the die pads of the second die, the third conductive circuits, the second conductive circuits, the conductive pillar, the first conductive circuits, the substrate conductive pillar, and the second bonding pads in turn.
(3) As to the structure, the first die is further connected with the outside through the first die pads of the first die, the first conductive circuits, the substrate conductive pillars, and the second bonding pads in turn.
(4) In the step S1 of the method of manufacturing the FOWLP unit, the substrate further includes at least one substrate conductive pillar penetrating the substrate dielectric layer, the first surface, and the second surface of the substrate. The substrate conductive pillar is exposed through the substrate to form a second bonding pad on the substrate.

### BRIEF DESCRIPTION OF THE DRAWINGS

FIG. 1 is a side sectional view of a first embodiment of a FOWLP unit according to the present invention;

FIG. 2 is a side sectional view of a substrate of the first embodiment according to the present invention;

FIG. 3 is a side sectional view showing a first dielectric layer disposed on the substrate of the embodiment in FIG. 2 according to the present invention;

FIG. 4 is a side sectional view showing first slots fully filled with a metal paste therein of the embodiment in FIG. 3 according to the present invention;

FIG. 5 is a side sectional view showing grinding of the metal paste to form first conductive circuits of the embodiment in FIG. 4 according to the present invention;

FIG. 6 is a side sectional view showing at least one first die arranged at the first conductive circuits of the embodiment in FIG. 5 according to the present invention;

FIG. 7 is a side sectional view showing a second dielectric layer disposed over the first die of the embodiment in FIG. 6 according to the present invention;

FIG. 8 is a side sectional view showing conductive pillars mounted in insertion holes of the embodiment in FIG. 7 according to the present invention;

FIG. 9 is a side sectional view showing second slots filled with a metal paste of the embodiment in FIG. 8 according to the present invention;

FIG. 10 is a side sectional view showing grinding of the metal paste to form second conductive circuits of the embodiment in FIG. 9 according to the present invention;

FIG. 11 is a side sectional view showing a third dielectric layer arranged at of the second conductive circuits of the embodiment in FIG. 10 according to the present invention;

FIG. 12 is a side sectional view showing third slots filled with a metal paste of the embodiment in FIG. 11 according to the present invention;

FIG. 13 is a side sectional view showing grinding of the metal paste to form third conductive circuits of the embodiment in FIG. 12 according to the present invention;

FIG. 14 is a side sectional view showing at least one second die arranged at the third conductive circuits of the embodiment in FIG. 13 according to the present invention;

FIG. 15 is a side sectional view showing solder balls mounted to first die pads in the embodiment in FIG. 14 according to the present invention;

FIG. 16 is a side sectional view of a second embodiment of a FOWLP unit according to the present invention;

FIG. 17 is a side sectional view of a substrate of the second embodiment according to the present invention;

FIG. 18 is a side sectional view showing a first dielectric layer disposed over the substrate of the embodiment in FIG. 17 according to the present invention;

FIG. 19 is a side sectional view showing first slots fully filled with a metal paste therein of the embodiment in FIG. 18 according to the present invention;

FIG. 20 is a side sectional view showing grinding of the metal paste to form first conductive circuits of the embodiment in FIG. 21 according to the present invention;

FIG. 21 is a side sectional view showing at least one first die arranged at the first conductive circuits of the embodiment in FIG. 29 according to the present invention;

FIG. 22 is a side sectional view showing a second dielectric layer disposed over the first die of the embodiment in FIG. 21 according to the present invention;

FIG. 23 is a side sectional view showing conductive pillars mounted in insertion holes of the embodiment in FIG. 22 according to the present invention;

FIG. 24 is a side sectional view showing second slots filled with a metal paste of the embodiment in FIG. 23 according to the present invention;

FIG. 25 is a side sectional view showing grinding of the metal paste to form second conductive circuits of the embodiment in FIG. 24 according to the present invention;

FIG. 26 is a side sectional view showing a third dielectric layer arranged at of the second conductive circuits of the embodiment in FIG. 25 according to the present invention;

FIG. 27 is a side sectional view showing third slots filled with a metal paste of the embodiment in FIG. 26 according to the present invention;

FIG. 28 is a side sectional view showing grinding of the metal paste to form third conductive circuits of the embodiment in FIG. 27 according to the present invention;

FIG. 29 is a side sectional view showing at least one second die arranged at the third conductive circuits of the embodiment in FIG. 28 according to the present invention;

FIG. 30 is a side sectional view showing solder balls mounted to first die pads in the embodiment in FIG. 29 according to the present invention.

### DETAILED DESCRIPTION OF THE PREFFERED EMBODIMENT

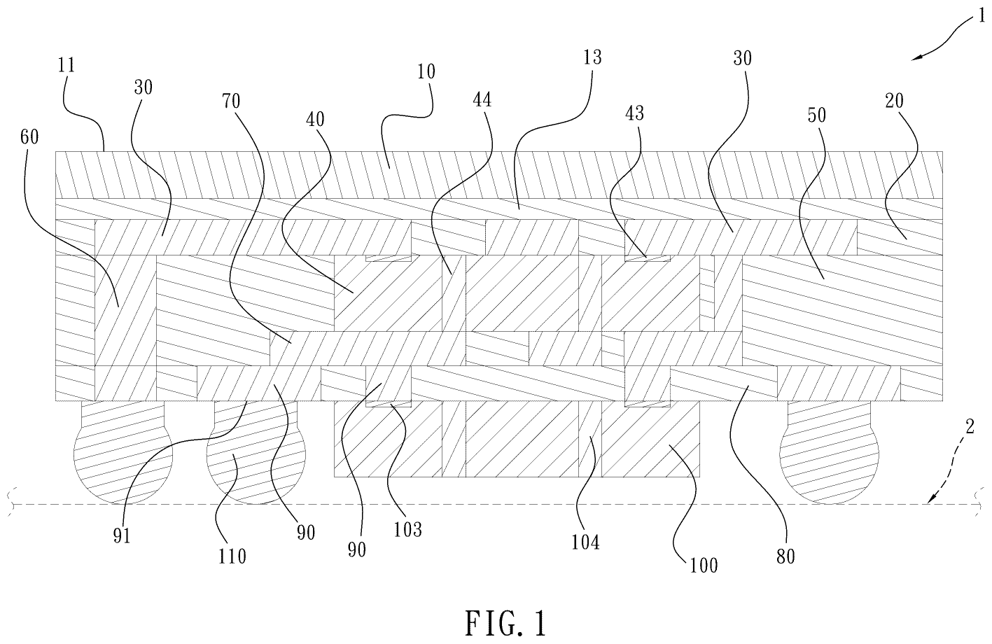

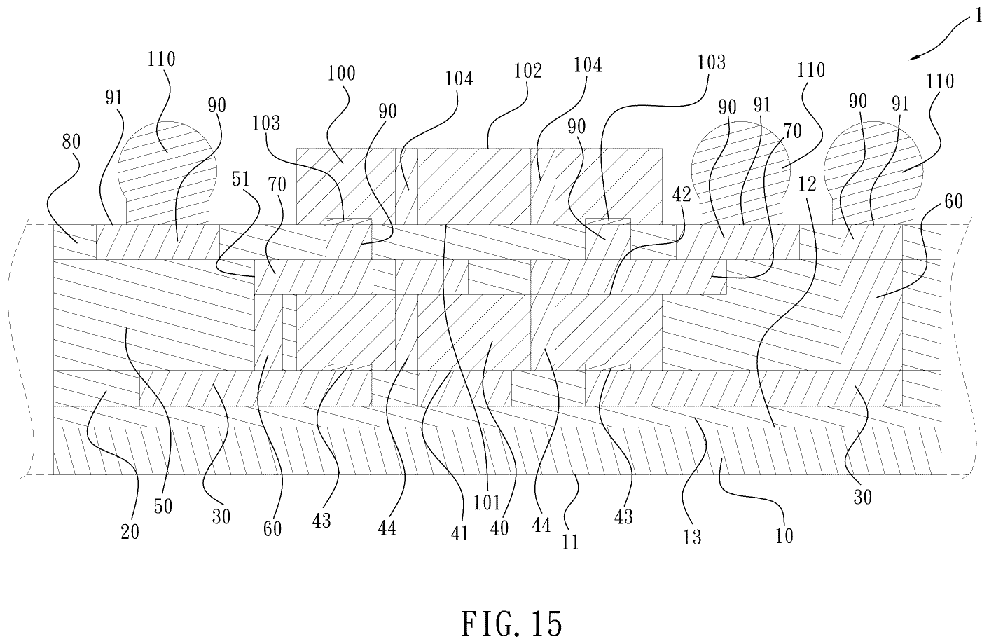

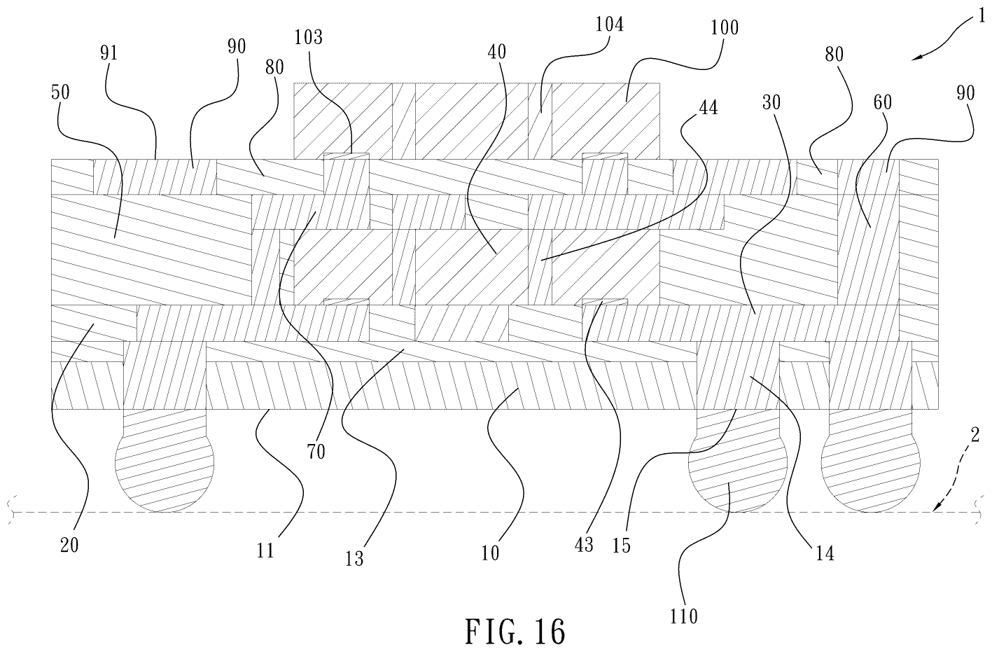

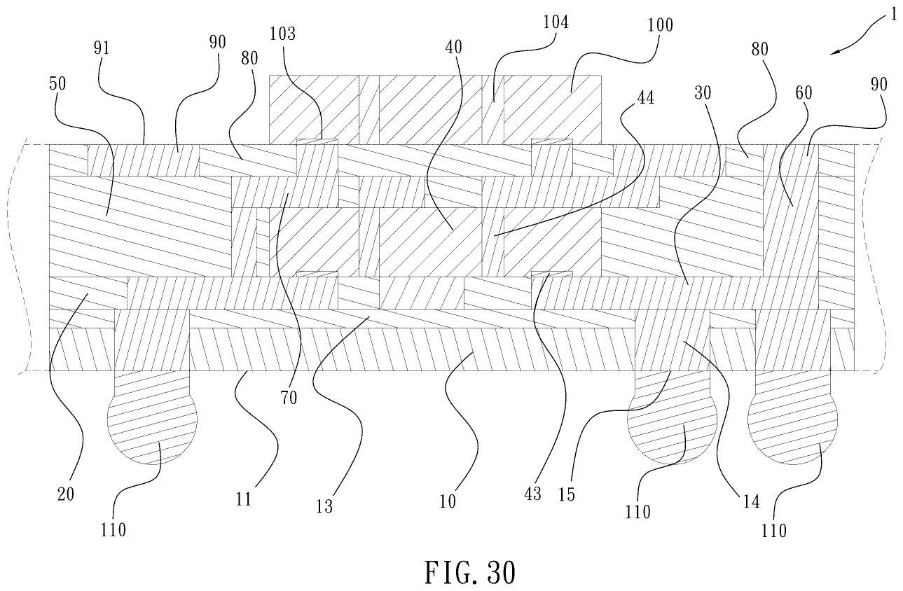

Refer to FIG. 1, FIG. 15, FIG. 16, and FIG. 30, a fan-out wafer-level packaging (FOWLP) unit 1 according to the present invention is provided. The FOWLP unit 1 includes a substrate 10, a first dielectric layer 20, a plurality of first conductive circuits 30, at least one first die 40, a second dielectric layer 50, at least one conductive pillar 60, a plurality of second conductive circuits 70, a third dielectric layer 80, a plurality of third conductive circuits 90, and at least one second die 100.

According to structures and types of the substrate 10 and electrical connection ways of the FOWLP unit 1 with the outside, different embodiments including the first embodiment shown in FIG. 1 and FIG. 15, and the second embodiment shown in FIG. 16 and FIG. 30 are provided.

The first embodiment of the FOWLP unit 1 shown in FIG. 1 and FIG. 15 is described below.

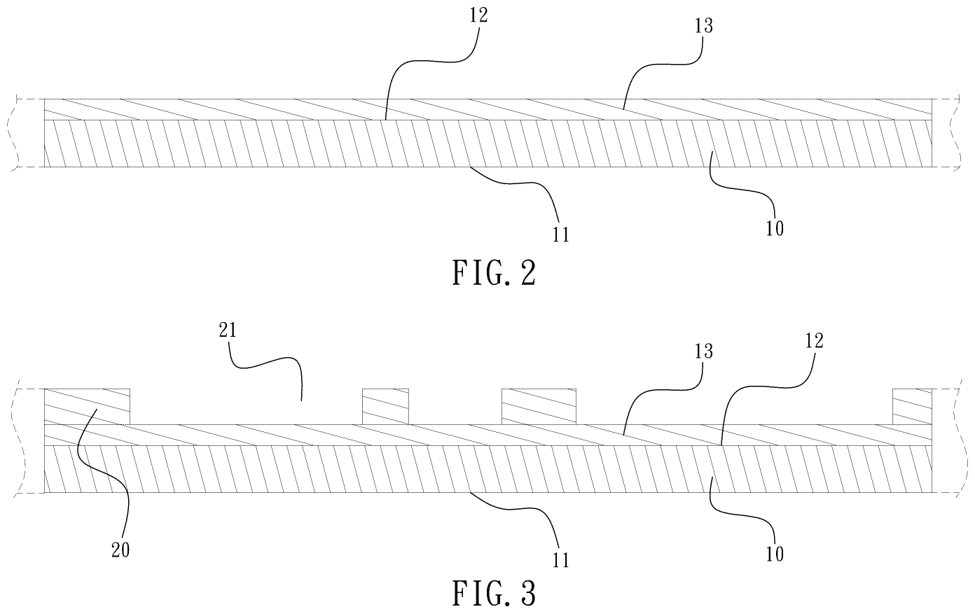

Refer to FIG. 2, the substrate 10 is provided with a first surface 11, a second surface 12 opposite to the first surface 11, and a substrate dielectric layer 13 disposed on the second surface 12.

Refer to FIG. 3, the first dielectric layer 20 is arranged over the substrate dielectric layer 13 of the substrate 10 and provided with at least first slot 21 extending in a horizontal direction.

Refer to FIG. 5, the respective first conductive circuits 30 are formed by a metal paste 30a filled into the respective first slots 21 correspondingly.

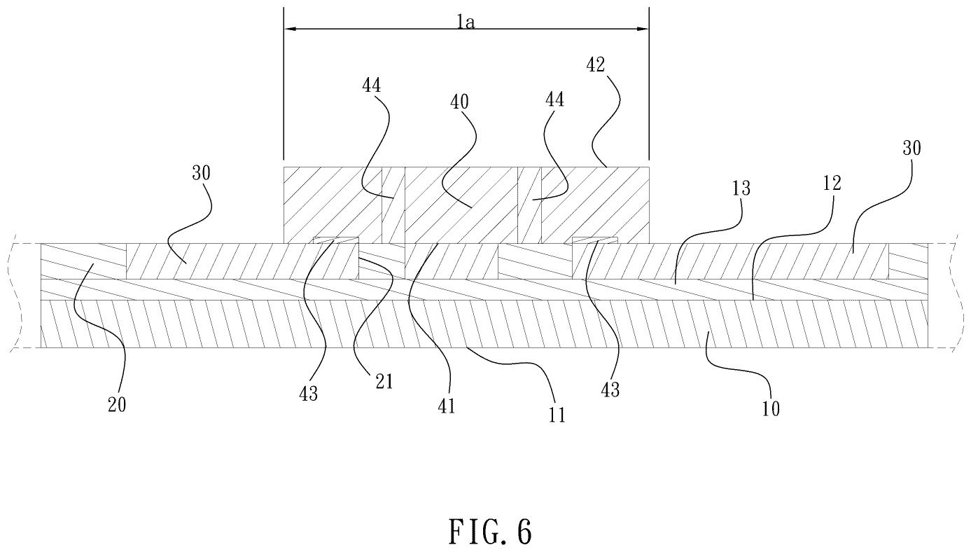

Refer to FIG. 6, the first die 40 is cut from a wafer and provided with a first surface 41 and a second surface 42 opposite to the first surface 41. A plurality of first die pads 43 is disposed on the first surface 41 while a range perpendicular to the second surface 42 of the first die 40 is defined as a chip area 1a. The first chip 40 is provided with at least one chip conductive pillar 40 penetrating the first surface 41 and the second surface 42 so that the first surface 41 is electrically connected to the second surface 42 by the conductive pillars 44, as shown in FIG. 6. The first surface 41 of the first die 40 is disposed on the first conductive circuits 30 by flip chip so that the first die pads 43 and the first conductive circuits 30 are electrically connected. In FIG. 6, there are two conductive pillars 44 of the first die 40, but not limited.

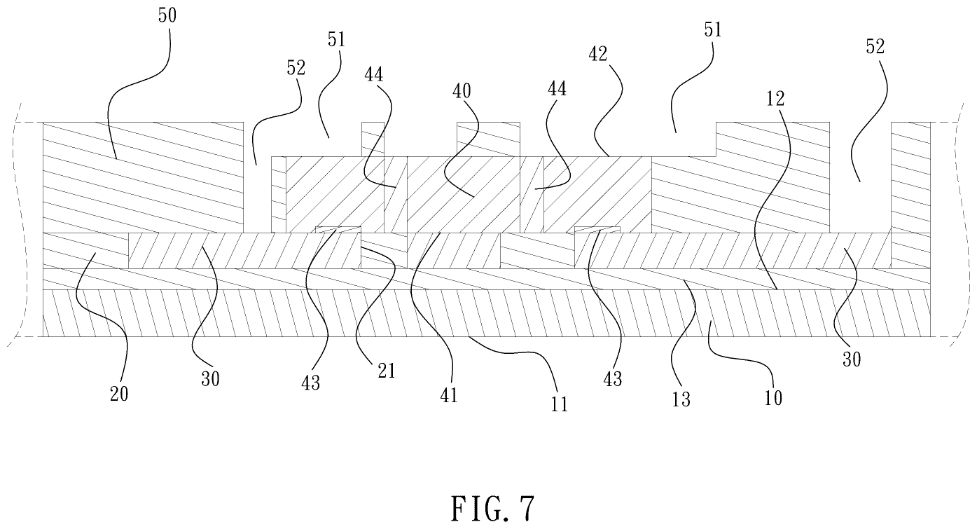

Refer to FIG. 7, the second dielectric layer 50 is disposed over the first dielectric layer 20 and covering the first die 40. The second dielectric layer 50 is provided with at least one second slot 51 extending in a horizontal direction and at least one insertion hole 52. The second slot 51 is communicating with the insertion hole 52 which is communicating with the first slot 21.

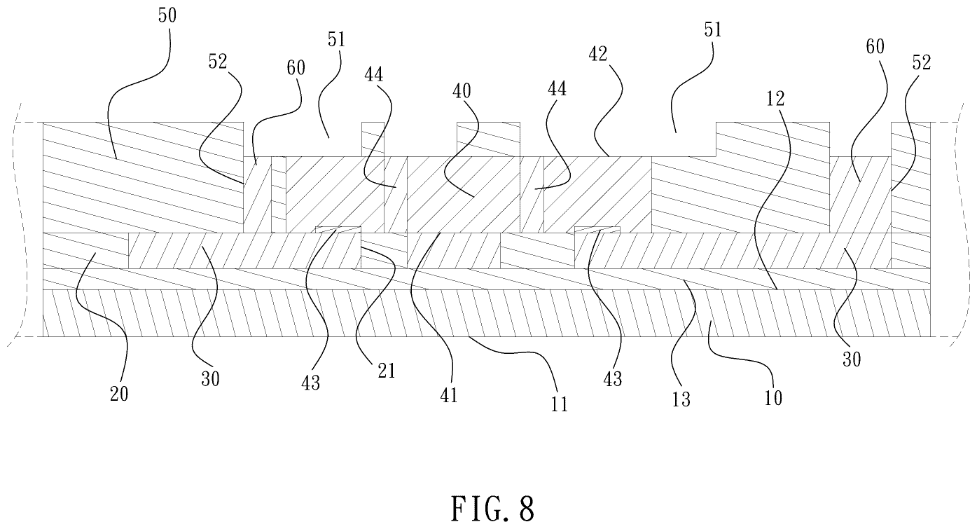

Refer to FIG. 8, the conductive pillar 60 is formed in the insertion hole 52 and exposed through the insertion hole 52. The conductive pillar 60 is electrically connected to the first conductive circuits 30.

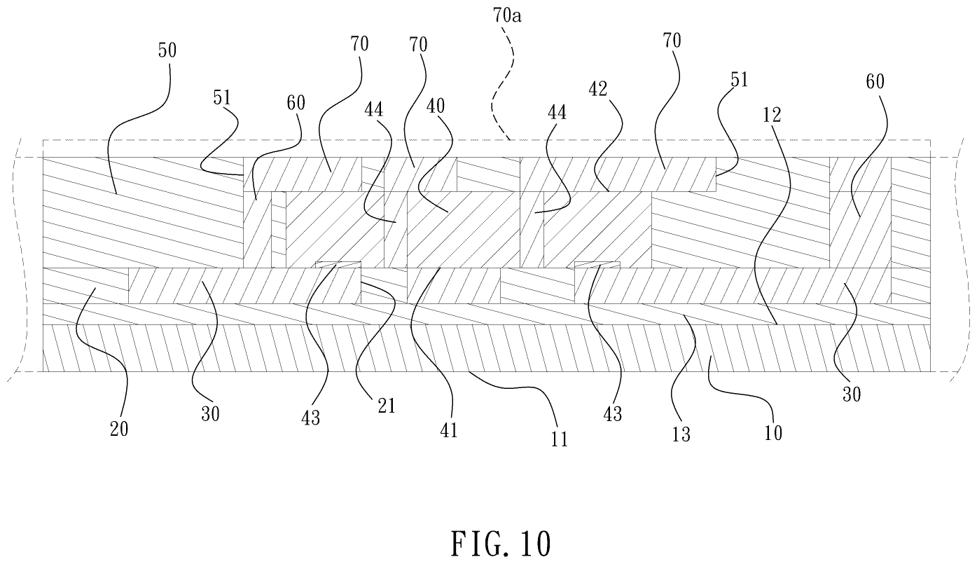

Refer to FIG. 10, the respective second conductive circuits 70 are formed by a metal paste 70a filled into the respective second slots 51 correspondingly. The second conductive circuits 70 are electrically connected to the conductive pillar 60.

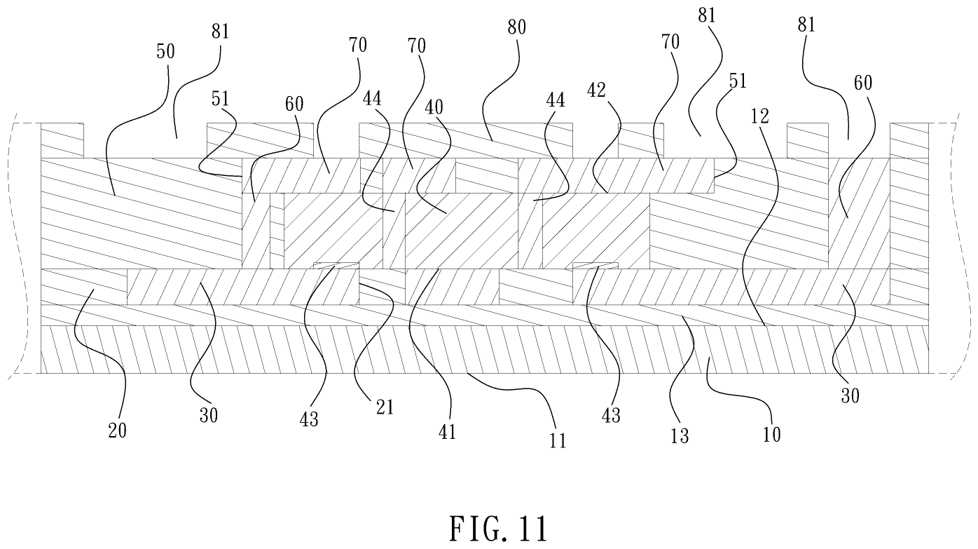

Refer to FIG. 11, the third dielectric layer 80 is disposed over the second dielectric layer 50 and the second conductive circuits 70. The third dielectric layer 80 is provided with at least one opening 81 extending in a horizontal direction.

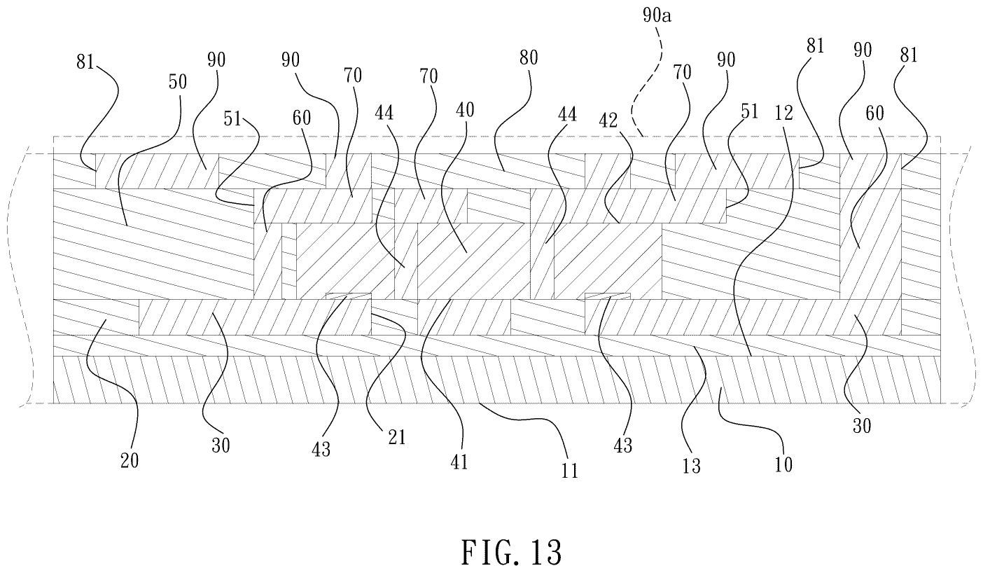

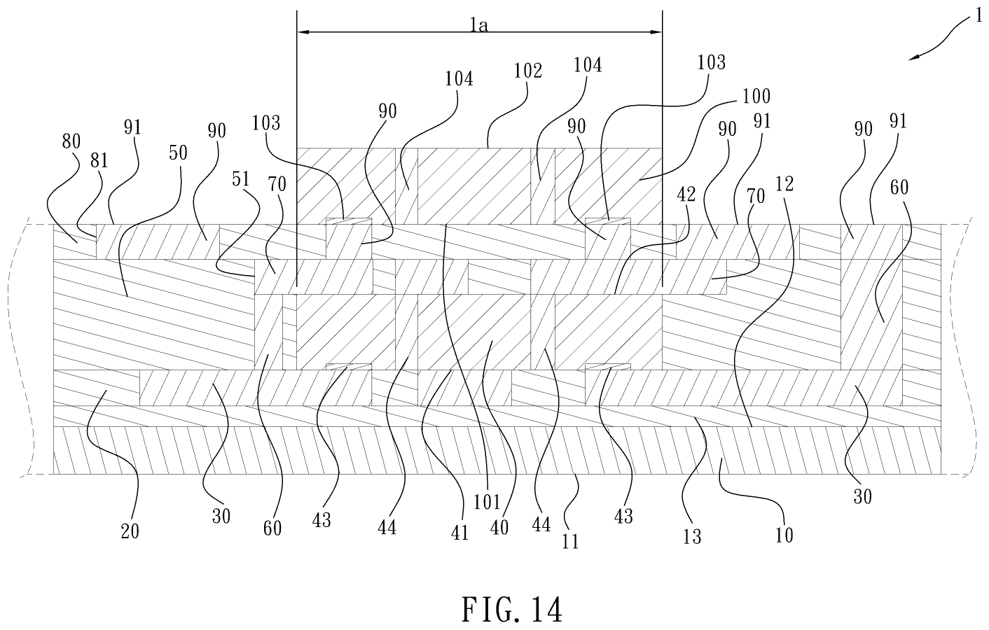

Refer to FIG. 13 and FIG. 14, the third conductive circuits 90 are formed by a metal paste 90a filled into the respective openings 81 correspondingly. At least one of the openings 81 is located around the chip area 1a on the second surface 42 of the first die 40. The third conductive circuits 90 are exposed through the openings 81 to form a first bonding pad 91 in each of the openings 81. The third conductive circuits 90 are electrically connected with the second conductive circuits 70. In FIG. 13, the number of the openings 81 of the FOWLP 1 is three, but not limited.

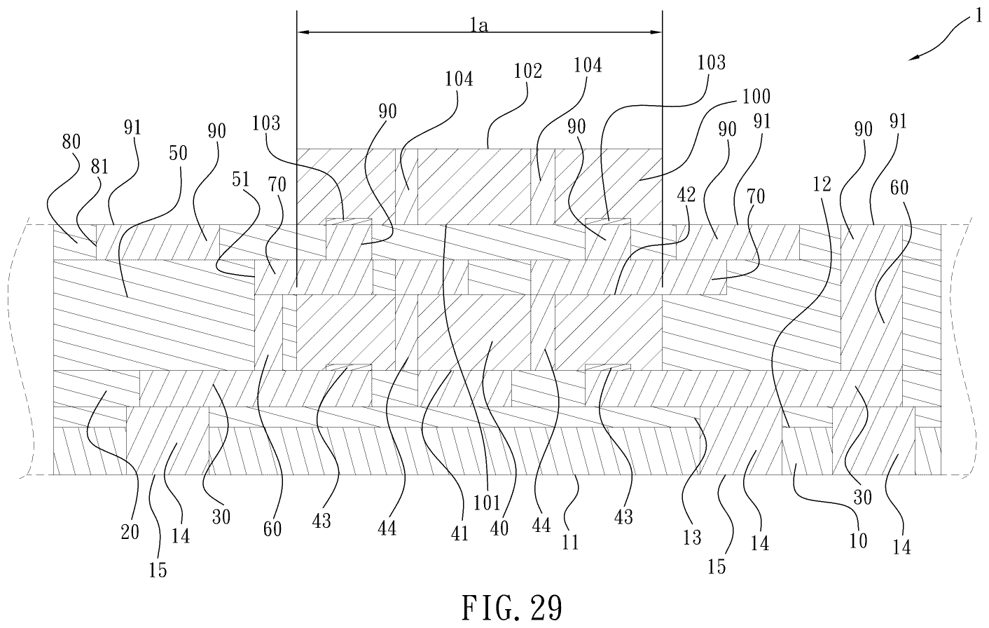

Refer to FIG. 14, the second die 100 is cut from a wafer and provided with a first surface 101 and a second surface 102 opposite to the first surface 101. A plurality of die pads 103 is disposed on the first surface 1. The second chip 100 is provided with at least one chip conductive pillar 104 penetrating the first surface 101 and the second surface 102 so that the first surface 101 is electrically connected to the second surface 102 by the conductive pillars 104, as shown in FIG. 6. The first surface 101 of the second die 100 is disposed on the third conductive circuits 90 by flip chip so that the die pads 103 and the third conductive circuits 90 are electrically connected. In FIG. 29, the number of the conductive pillars 104 of the second die 100 is two, but not limited.

Refer to FIG. 14, the second die 100 is electrically connected to the first die 40 through the die pads 103, the third conductive circuits 90, the second conductive circuits 70, the conductive pillars 60, the first conductive circuits 30, and the first die pads 43 of the first die 40 in turn.

Refer to FIG. 14, the second die 100 is electrically connected to the outside through the die pads 103, the third conductive circuits 90, the second conductive circuits 70, the third conductive circuits 90, and the first die pads 91 located around the chip area 1a on the second surface 42 of the first die 40 in turn.

Refer to FIG. 14, the first die 40 is electrically connected to the outside through the first die pads 43 of the first die 40, the first conductive circuits 30, the conductive pillars 60, the second conductive circuits 70, the third conductive circuits 90, and the first die pads 91 located around the chip area 1a on the second surface 42 of the first die 40 in turn. Thereby the FOWLP unit 1 is formed.

A method of manufacturing the FOWLP unit 1 includes the following steps.

Step S1: providing a substrate 10 having a first surface 11 and a second surface 12 opposite to each other. A substrate dielectric layer 13 is disposed on the second surface 12, as shown in FIG. 2.

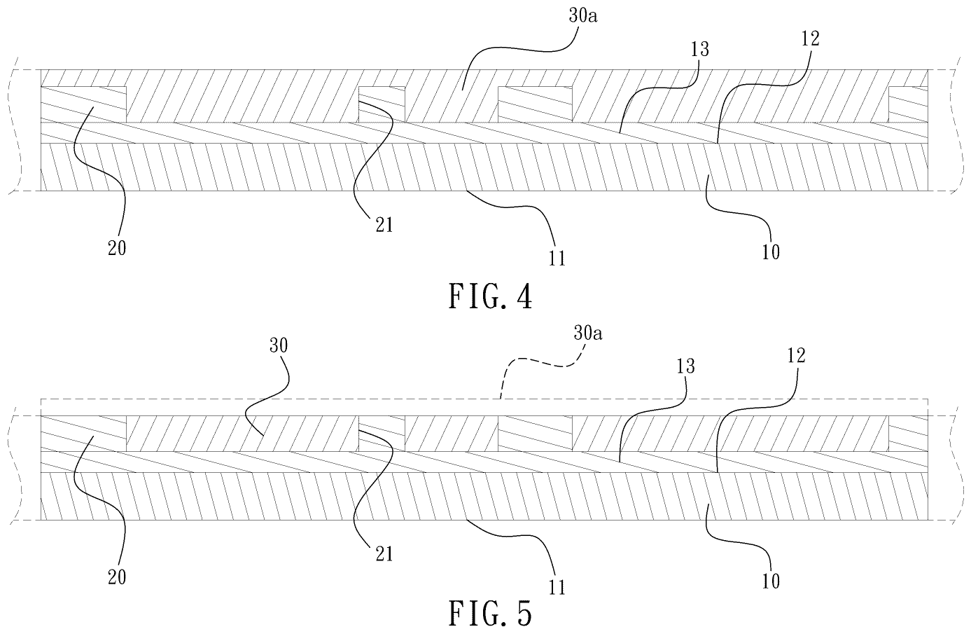

Step S2: producing a plurality of first conductive circuits 30 on the substrate dielectric layer 13 of the substrate 10 by filling a metal paste into slots and grinding the metal paste. First paving a first dielectric layer 20 over the second surface 12 of the substrate 10, as shown in FIG. 3. Then forming a plurality of first slots 21 horizontally on the first dielectric layer 20. Next filling a metal paste 30a into the first slots 21 and a level of the metal paste 30a is higher than a surface of the first dielectric layer 20, as shown in FIG. 4. Lastly grinding the metal paste 30a with the level higher than the surface of the first dielectric layer 20 to make a surface of the metal paste 30a flush with the surface of the first dielectric layer 20 and form a plurality of the first conductive circuits 30, as shown in FIG. 5.

Step S3: arranging a plurality of first dies 40 cut from at least one wafer on the second surface 12 of the substrate 10 with an interval between the two adjacent first dies 40, as shown in FIG. 6. Each of the first dies 40 includes a first surface 41 and a second surface 42 opposite to the first surface 41. The first surface 41 is provided with a plurality of first die pads 43 and a range perpendicular to the second surface 42 is defined as a chip area 1a. The first chip 40 includes at least one chip conductive pillar 44 penetrating the first surface 41 and the second surface 42. The first surface 41 of the first die 40 is disposed on the first conductive circuits 30 by flip chip so that the first die pads 43 and the first conductive circuits 30 are electrically connected.

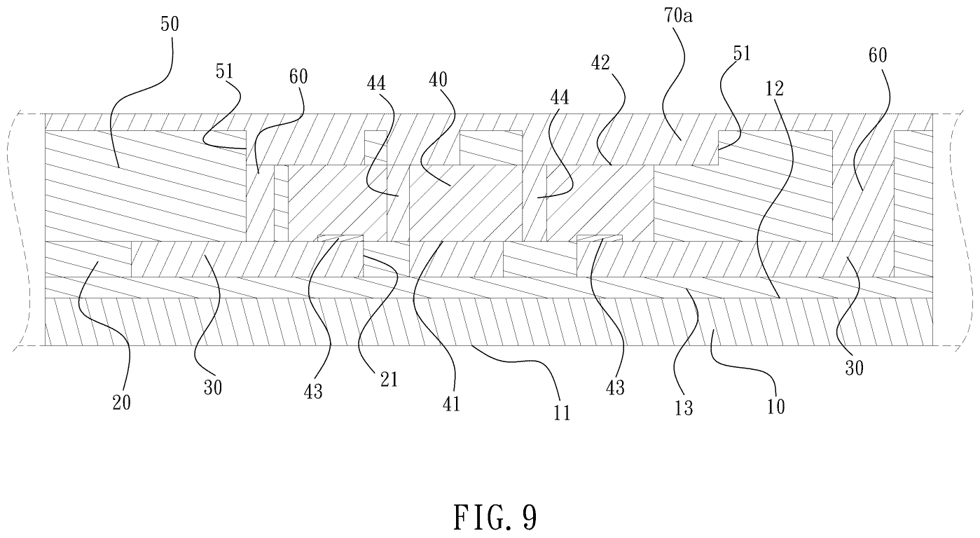

Step S4: producing a plurality of second conductive circuits 70 on the second surface 42 of the first die 40 by filling a metal paste into slots and grinding the metal paste. First paving a second dielectric layer 50 over the second surface 12 of the substrate 10 and the respective first dies 40. The second dielectric layer 50 covers the respective first dies 40, as shown in FIG. 7. Then forming a plurality of second slots 51 horizontally on the second dielectric layer 50 and a plurality of insertion holes 52 penetrating the second dielectric layer 50. The first die pads 43 of the first die 40 are exposed through the second slots 51 and the insertion holes 52 are communicating with the first slots 21 and the second slots 51. Later as shown in FIG. 8, forming a conductive pillar 60 in the insertion hole 52 and filling a metal paste 70a into the second slots 51 and a level of the metal paste 70a is higher than a surface of the second dielectric layer 50, as shown in FIG. 9. Lastly grinding the metal paste 70a with the level higher than the surface of the second dielectric layer 50 to make a surface of the metal paste 70a flush with the surface of the second dielectric layer 50 and form a plurality of the second conductive circuits 70, as shown in FIG. 10.

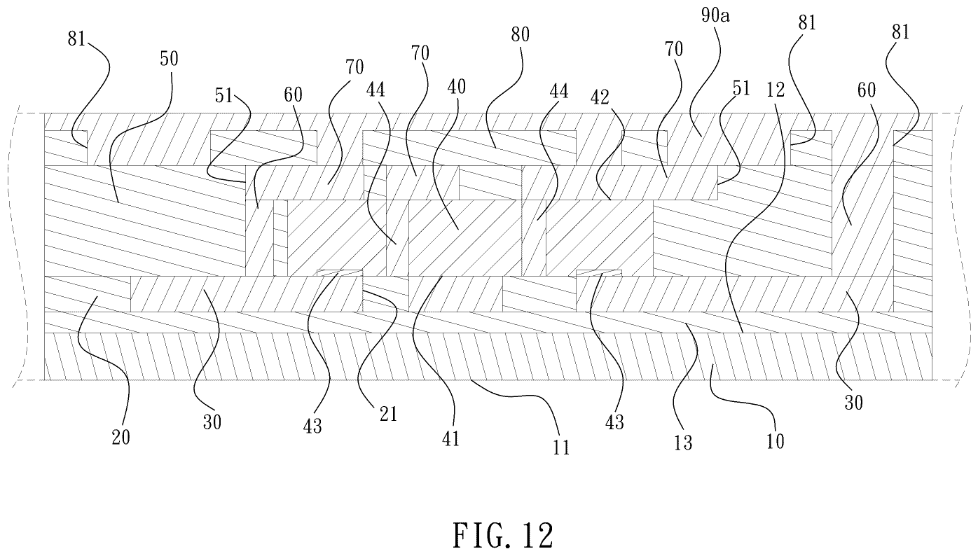

Step S5: producing a plurality of third conductive circuits 90 on the second dielectric layer 50 by filling a metal paste into slots and grinding the metal paste. First paving a third dielectric layer 80 over the second dielectric layer 50. Then forming a plurality of openings 81 horizontally on the third dielectric layer 80, as shown in FIG. 11. Later filling a metal paste 90a into the openings 81 and a level of the metal paste 90a is higher than a surface of the third dielectric layer 80, as shown in FIG. 12. Lastly grinding the metal paste 90a with the level higher than the surface of the third dielectric layer 80 to make a surface of the metal paste 90a flush with the surface of the third dielectric layer 80 and form a plurality of the third conductive circuits 90, as shown in FIG. 13. At least one of the openings 81 is located around the chip area 1a on the second surface 42 of the first die 40, as shown in FIG. 14. The third conductive circuits 90 are exposed through the openings 81 to form a first bonding pad 91 in each of the openings 81, as shown in FIG. 14.

Step S:6 arranging a plurality of second dies 100 cut from at least one wafer at the third conductive circuits 30 with an interval between the two adjacent second dies 100, as shown in FIG. 14. Each of the second dies 100 includes a first surface 101 and a second surface 102 opposite to the first surface 101. The first surface 101 is provided with a plurality of die pads 103. Each of the second dies 100 is provided with at least one chip conductive pillar 104 penetrating the first surface 101 and the second surface 102. The first surface 101 of the second die 100 is disposed on the third conductive circuits 90 by flip chip so that the die pads 103 and the third conductive circuits 90 are electrically connected.

Step S7: performing cutting to form a plurality of the FOWLP units 1, as shown in FIG. 14.

The step S2, step S4, and the step S5 of the present method mentioned above are considered as key steps in production of RDL of the FOWLP unit 1 and all are precise and easily-implemented steps. Thus the manufacturing process is simplified so that the FOWLP unit 1 produced is still having a certain degree of compact design under condition that the first conductive circuits 30, the second conductive circuits 70, and the third conductive circuits 90 in the RDL have electrical extension in the XY plane and interconnections. This especially helps in reduction of the thickness of the FOWLP unit 1. Thus not only production cost is reduced, use efficiency and reliability of the FOWLP unit 1 are improved effectively.

As to the second embodiment of the FOWLP unit 1 shown in FIG. 16 and FIG. 30, it is described below.

The difference between the second embodiment and the first embodiment is in that the structure or type of the substrate 10 and the electrical connection way the FOWLP unit 1 is connected with the outside. As the first embodiment shown in FIG. 1-15, the structure/type and manufacturing process of the second embodiment are shown in FIG. 16 to FIG. 20. The same parts of the first and the second embodiments are not described in detail. The main difference between the first and the second embodiments is described as following.

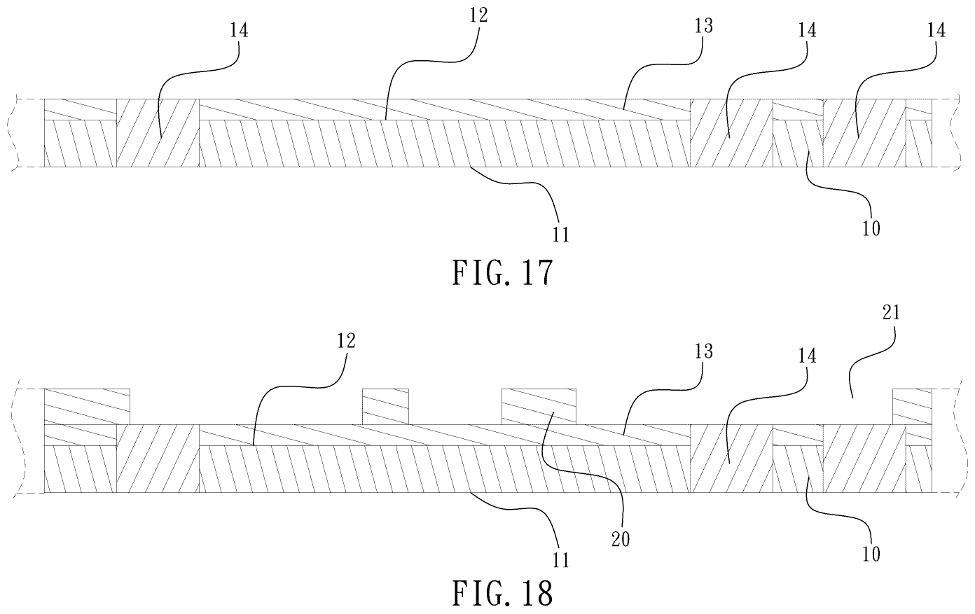

The substrate 10 of the second embodiment further includes at least one substrate conductive pillar 14 penetrating the substrate dielectric layer 13, the first surface 11, and the second surface 12, as shown in FIG. 17. The substrate conductive pillar 14 is exposed through the first surface 11 of the substrate 10 to form a second bonding pad 15 on the substrate 10, as shown in FIG. 29.

As to the second embodiment, the first conductive circuits 30 are formed by a metal paste 30a filled into the first slots 21, as shown in FIG. 20. The first conductive circuits 30 are electrically connected to the substrate conductive pillar 14, as shown in FIG. 20.

In the second embodiment, the second die 100 is further connected with the outside through the die pads 103 of the second die 100, the third conductive circuits 90, the second conductive circuits 70, the conductive pillar 60, the first conductive circuits 30, the substrate conductive pillars 14, and the second bonding pads 15 in turn, as shown in FIG. 29.

In the second embodiment, the first die 40 is further connected with the outside through the first die pads 43 of the first die 40, the first conductive circuits 30, the substrate conductive pillars 14, and the second bonding pads 15 in turn, as shown in FIG. 29.

In the step S1 of the method of manufacturing the FOWLP unit 1 of the second embodiment, the substrate 10 further includes the substrate conductive pillar 14 penetrating the substrate dielectric layer 13, the first surface 11, and the second surface 12, as shown in FIG. 17. The substrate conductive pillar 14 is exposed through the substrate 10 to form a second bonding pad 15 on the substrate 10, as shown in FIG. 17.

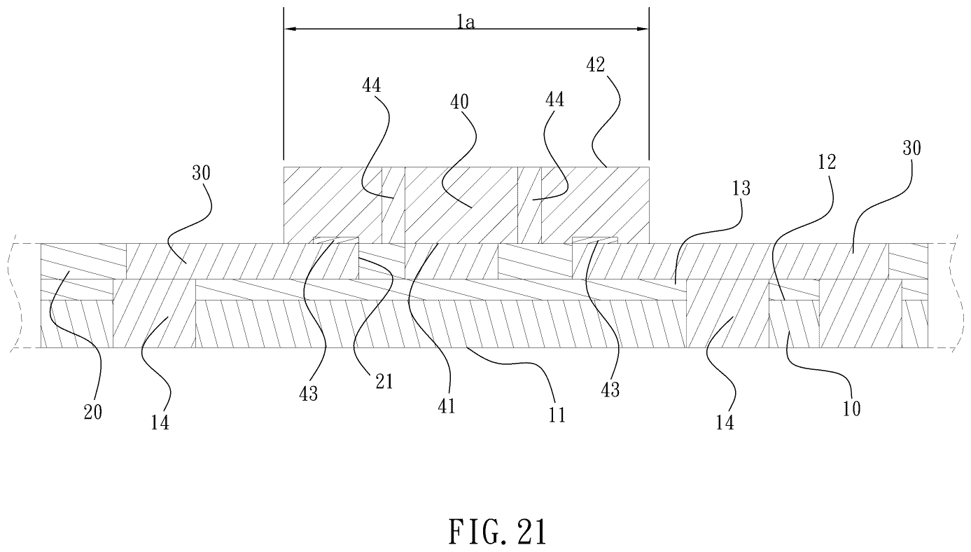

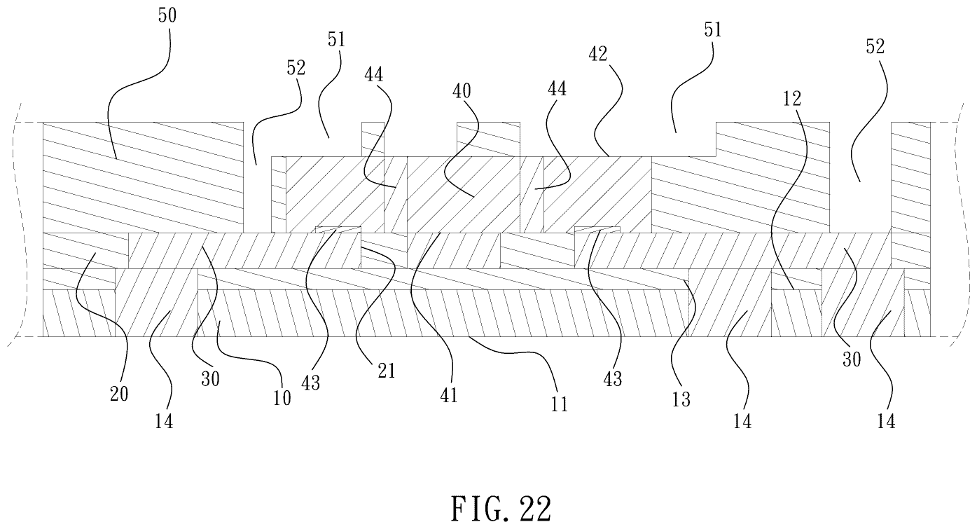

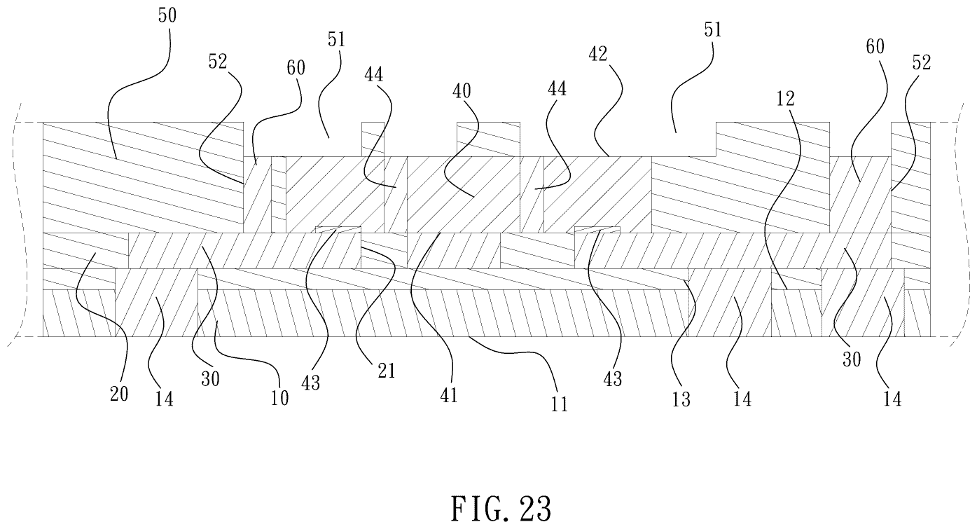

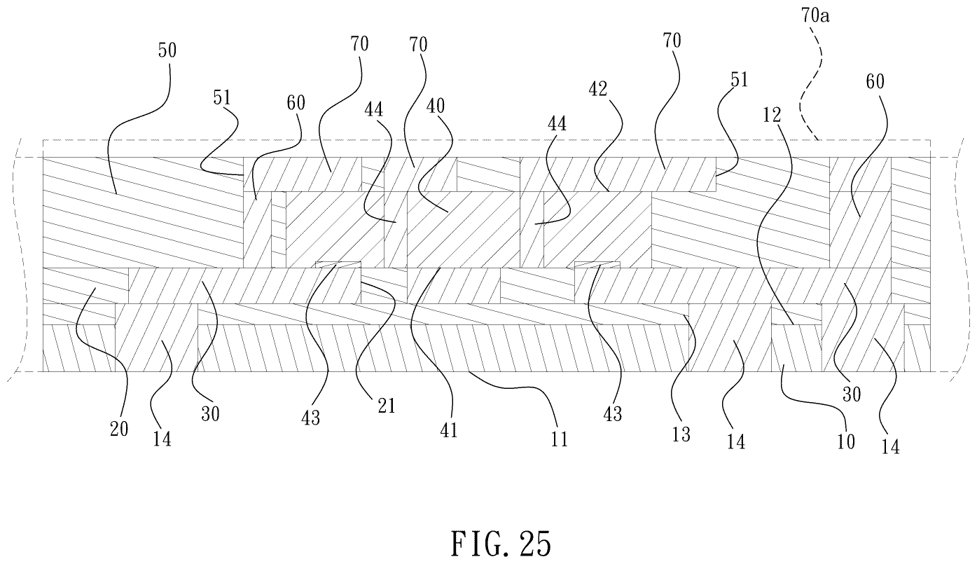

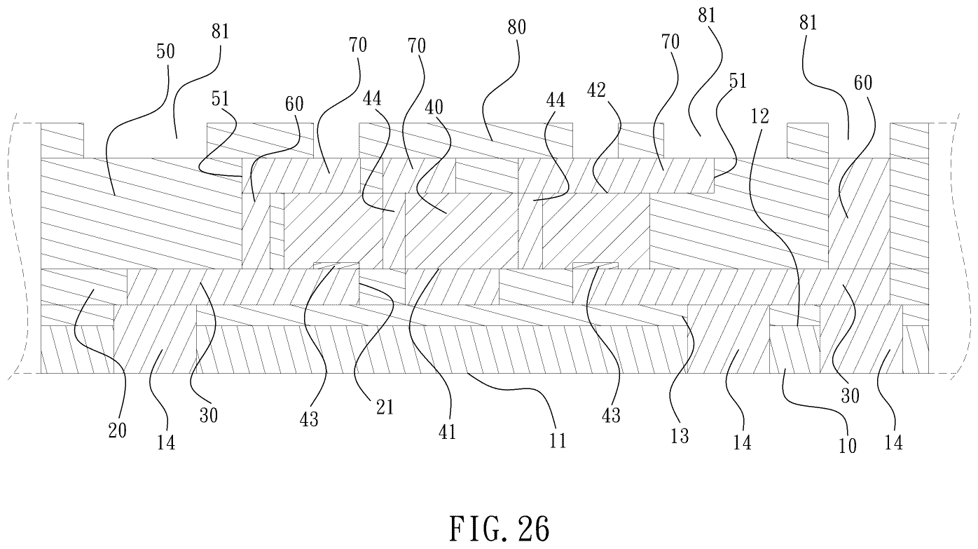

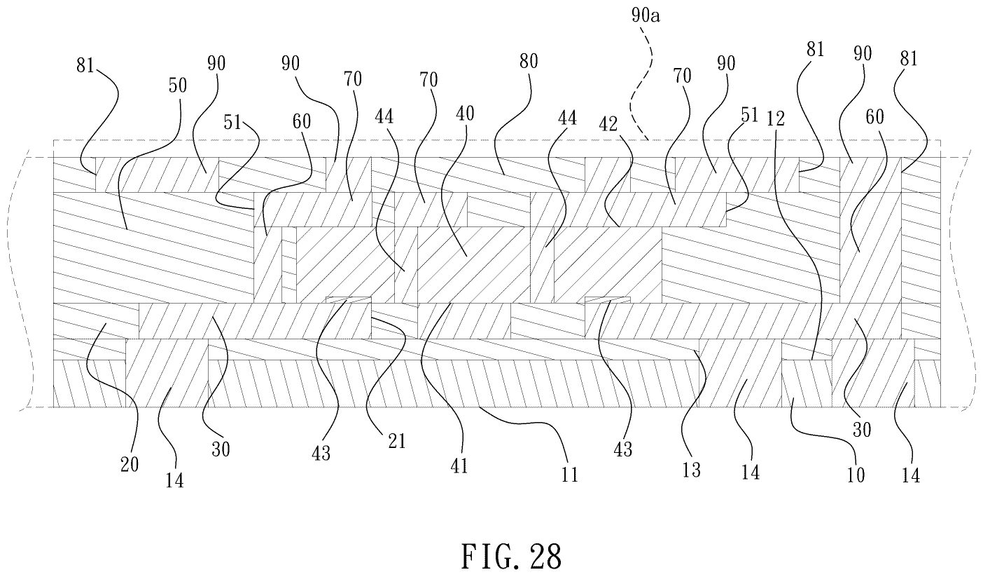

In the second embodiment, the first die 40 shown in FIG. 21, the second dielectric layer 50 shown in FIG. 22, the conductive pillar 60 shown in FIG. 23, the second conductive circuits 70 shown in FIG. 25, the third dielectric layer 80 shown in FIG. 26, the third conductive circuits 90 shown in FIG. 28, the second die 100 shown in FIG. 29, and the steps S2-S7 in the manufacturing method are all the same as those of the first embodiment and thus not described in detail.

Refer to FIG. 2 and FIG. 17, the substrate 10 includes silicon substrate, glass substrate, and ceramic substrate, but not limited. This is beneficial to development and diverse applications of the product.

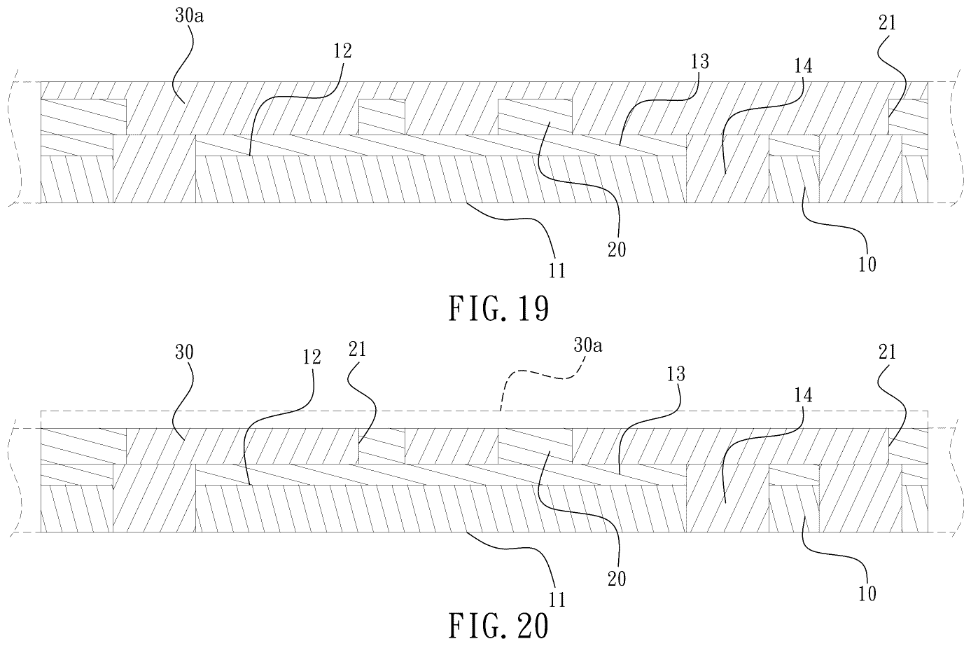

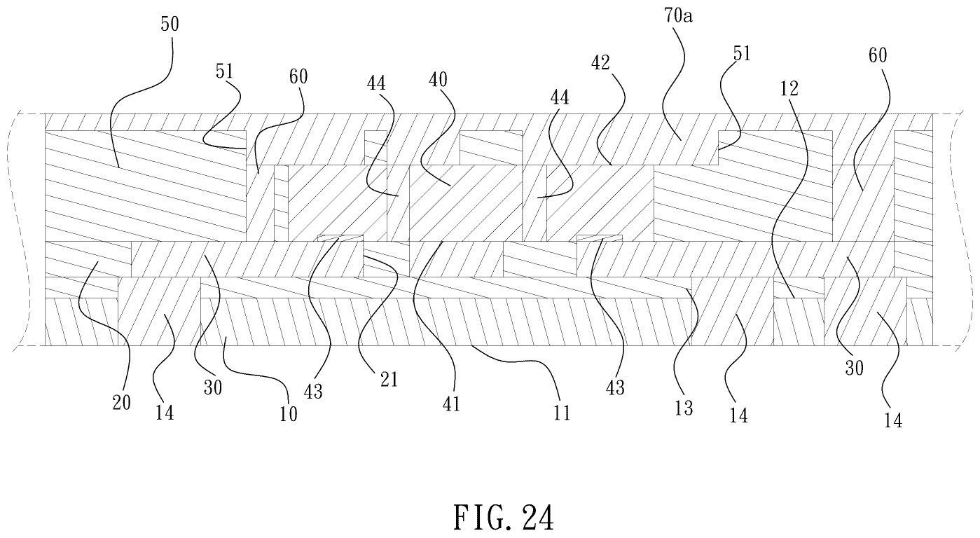

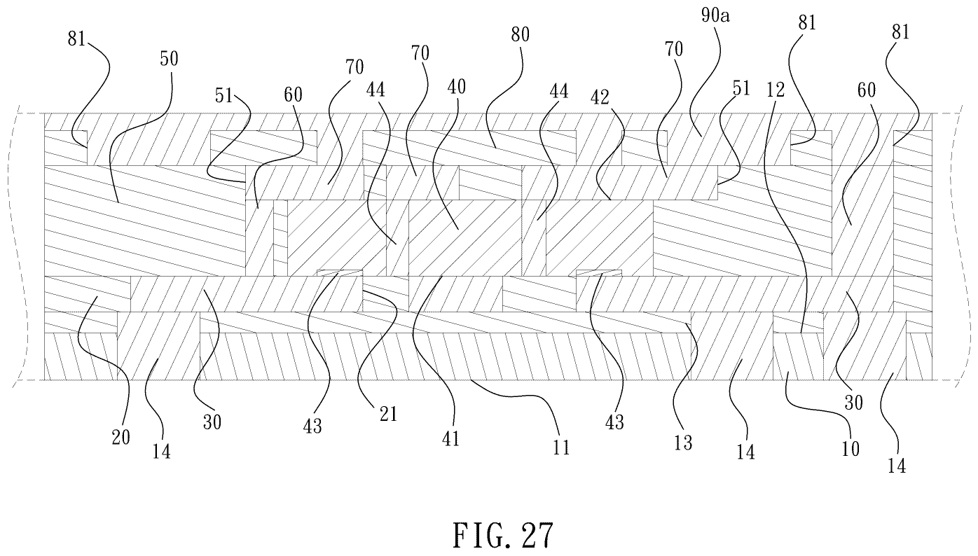

Refer to FIG. 5, FIG. 10, FIG. 13, FIG. 19, FIG. 24, and FIG. 27, the metal pastes 30a, 70a, 90a used to form the first, the second, and the third conductive circuits 30, 70, 90 include silver paste, nano-scale silver paste, copper paste, and nano-scale copper paste, but not limited. This is beneficial to development and diverse applications of the product. The nano-scale silver paste has features of low cost, high conductivity, and low-temperature sintering. Since nano-scale silver paste is a common material, no detail is provided.

Refer to FIG. 15 and FIG. 30, a solder ball 110 is mounted to each of the openings 81 and electrically connected with the first die pad 91 in the opening 81.

Refer to FIG. 1 and FIG. 16, the FOWLP unit 1 is electrically connected and fixed on a printed circuit board (PCB) 2 by the solder balls 110, but not limited.

Compared with the FOWLP unit available now, the present FOWLP unit 1 has the following advantages.

(1) The FOWLP unit 1 is produced by the steps S2, S4, and S5 of the present method. The present method not only helps in reduction of the thickness of the packaging unit, but also reduces cost by the simplified process. The use efficiency and reliability of the FOWLP unit 1 are improved effectively.

(2) The steps S2, S4 and S5 of the method of manufacturing the FOWLP doesn't use chemical plating or electroplating available now so that cost and contamination generated during the manufacturing process can be reduced.

(3) By structure design and relative connections between the respective component, electrical connections between the dies inside the packaging unit and the outside and between the dies outside the packaging unit and the inside can be achieved. Thereby the number of the chips can be increased for providing higher performance or products with more functions. The products are more competitive in the market.

(4) The first/second die 40/100 of the present invention includes at least one chip conductive pillar 44/104 penetrating the first surface 41/101 and the second surface 42/102 so that the first surface 41/101 of the first/second die 40/100 is electrically connected to the second surface 42/102 by the chip conductive pillar 44/104. Thereby electrical connection of the products to the outside is more diversified.

Additional advantages and modifications will readily occur to those skilled in the art. Therefore, the invention in its broader aspects is not limited to the specific details, and representative devices shown and described herein. Accordingly, various modifications may be made without departing from the spirit or scope of the general inventive concept as defined by the appended claims and their equivalent.

1. A fan-out wafer-level packaging (FOWLP) unit comprising
a substrate provided with a first surface and a second surface opposite to the first surface, and a substrate dielectric layer disposed on the second surface;
a first dielectric layer arranged over the substrate dielectric layer of the substrate and provided with at least first slot extending horizontally;
a plurality of first conductive circuits formed by a metal paste filled into the first slots;
at least one first die cut from a wafer and having a first surface and a second surface opposite to the first surface; a plurality of first die pads disposed on the first surface; a range perpendicular to the second surface of the first die defined as a chip area; wherein the first chip is having at least one chip conductive pillar penetrating the first surface and the second surface so that the first surface is electrically connected to the second surface by the conductive pillar; wherein the first surface of the first die is disposed on the first conductive circuits by flip chip so that the first die pads and the first conductive circuits are electrically connected;
a second dielectric layer disposed over the first dielectric layer and covering the first die; the second dielectric layer having at least one second slot extending horizontally and at least one insertion hole; the second slot communicating with the insertion hole which is communicating with the first slot;
at least one conductive pillar formed in the insertion hole and exposed through the insertion hole; wherein the conductive pillar is electrically connected to the first conductive circuits;
a plurality of second conductive circuits formed by a metal paste filled into the second slots; wherein the second conductive circuits are electrically connected to the conductive pillar;
a third dielectric layer disposed over the second dielectric layer and the second conductive circuits; the third dielectric layer provided with at least one opening extending horizontally;
a plurality of third conductive circuits formed by a metal paste filled into the openings; wherein at least one of the openings is located around the chip area on the second surface of the first die; wherein the third conductive circuits are exposed through the openings to form a first bonding pad in each of the openings; wherein the third conductive circuits are electrically connected with the second conductive circuits; and
at least one second die cut from a wafer and provided with a first surface and a second surface opposite to the first surface; a plurality of die pads disposed on the first surface; the second chip provided with at least one chip conductive pillar penetrating the first surface and the second surface so that the first surface is electrically connected to the second surface by the conductive pillars; wherein the first surface of the second die is disposed on the third conductive circuits by flip chip so that the die pads of the second die and the third conductive circuits are electrically connected;
wherein the second die is electrically connected to the first die through the die pads of the second die, the third conductive circuits, the second conductive circuits, the conductive pillar, the first conductive circuits, and the first die pads of the first die in turn; wherein the second die is electrically connected to the outside through the die pads of the second die, the third conductive circuits, the second conductive circuits, the third conductive circuits, and the first die pads located around the chip area on) the second surface of the first die in turn; wherein the first die is electrically connected to the outside through the first die pads of the first die, the first conductive circuits, the conductive pillars, the second conductive circuits, the third conductive circuits, and the first die pads located around the chip area on the second surface of the first die in turn; thereby the FOWLP unit is formed;
wherein a method of manufacturing the FOWLP unit comprising the steps of:
Step S1: providing a substrate having a first surface and a second surface opposite to the first surface and having a substrate dielectric layer on the second surface;
Step S2: producing a plurality of first conductive circuits on the substrate dielectric layer by filling a metal paste into slots and grinding the metal paste; first paving a first dielectric layer over the second surface of the substrate; then forming a plurality of first slots horizontally on the first dielectric layer; next filling a metal paste into the first slots and allowing a level of the metal paste higher than a surface of the first dielectric layer; lastly grinding the metal paste with the level higher than the surface of the first dielectric layer to make a surface of the metal paste flush with the surface of the first dielectric layer and form a plurality of the first conductive circuits;
Step S3: arranging a plurality of first dies cut from at least one wafer at the second surface of the substrate with an interval between the two adjacent first dies; each of the first dies having a first surface and a second surface opposite to each other; the first surface provided with a plurality of first die pads and a range perpendicular to the second surface being defined as a chip area; wherein the first chip includes at least one chip conductive pillar penetrating the first surface and the second surface of the first die; wherein the first surface of the first die is disposed on the first conductive circuits by flip chip so that the first die pads of the first die and the first conductive circuits are electrically connected;
Step S4: producing a plurality of second conductive circuits on the second surface of the first die by filling a metal paste into slots and grinding the metal paste; first paving a second dielectric layer over the second surface of the substrate and the first dies; and the second dielectric layer covering the first dies; then forming a plurality of second slots horizontally on the second dielectric layer and a plurality of insertion holes penetrating the second dielectric layer; next exposing the first die pads of the first die through the second slots and communicating the insertion holes with the first slots and the second slots; later forming a conductive pillar in the insertion hole, filling a metal paste into the second slots, and allowing a level of the metal paste higher than a surface of the second dielectric layer; lastly grinding the metal paste with the level higher than the surface of the second dielectric layer to make a surface of the metal paste flush with the surface of the second dielectric layer and form a plurality of the second conductive circuits;
Step S5: producing a plurality of third conductive circuits on the second dielectric layer by filling a metal paste into slots and grinding the metal paste; first paving a third dielectric layer over the second dielectric layer; then forming a plurality of openings horizontally on the third dielectric layer; later filling a metal paste into the openings and allowing a level of the metal paste higher than a surface of the third dielectric layer; lastly grinding the metal paste with the level higher than the surface of the third dielectric layer to make a surface of the metal paste flush with the surface of the third dielectric layer and form a plurality of the third conductive circuits; wherein at least one of the openings is located around the chip area on the second surface of the first die; wherein the third conductive circuits are exposed through the openings to form a first bonding pad in each of the openings;
Step S6: arranging a plurality of second dies cut from at least one wafer at the third conductive circuits with an interval between the two adjacent second dies; wherein each of the second dies includes a first surface and a second surface opposite to the first surface; the first surface is provided with a plurality of die pads; wherein each of the second dies is provided with at least one chip conductive pillar penetrating the first surface and the second surface of the second die; wherein the first surface of the second die is disposed on the third conductive circuits by flip chip so that the die pads of the second die and the third conductive circuits are electrically connected; and
Step S7: performing cutting to form a plurality of the FOWLP units.

2. The FOWLP unit as claimed in claim 1, wherein the substrate includes a silicon substrate, a glass substrate, and a ceramic substrate.

3. The FOWLP unit as claimed in claim 1, wherein the metal pastes which form the first conductive circuits, the second conductive circuits, and the third conductive circuits include silver paste, nano-scale silver paste, copper paste, and nano-scale copper paste.

4. The FOWLP unit as claimed in claim 1, wherein a solder ball is mounted to each of the openings and electrically connected with the first die pad in the opening.

5. The FOWLP unit as claimed in claim 4, wherein FOWLP unit is electrically connected and fixed on a printed circuit board (PCB) by the solder balls.

6. The FOWLP unit as claimed in claim 1, wherein the substrate further includes at least one substrate conductive pillar penetrating the substrate dielectric layer, the first surface, and the second surface of the substrate; wherein the substrate conductive pillar is exposed through the first surface of the substrate to form a second bonding pad on the substrate; wherein the first conductive circuits are electrically connected to the substrate conductive pillar; wherein the second die is further connected with the outside through the die pads of the second die, the third conductive circuits, the second conductive circuits, the conductive pillar, the first conductive circuits, the substrate conductive pillar, and the second bonding pads in turn; wherein the first die is further connected with the outside through the first die pads of the first die, the first conductive circuits, the substrate conductive pillar, and the second bonding pads in turn; wherein in the step S1 of the method of manufacturing the FOWLP unit, the substrate further includes at least one substrate conductive pillar penetrating the substrate dielectric layer, the first surface, and the second surface of the substrate.
